(19) United States
(12) Patent Application Publication
(10) Pub. No.: US 2025/0301840 A1
(43) Pub. Date: Sep. 25, 2025

(54) DISPLAY DEVICE

(71) Applicant: AUO Corporation, Hsinchu City (TW)

(72) Inventors: Chi-Min Teng, Hsinchu City (TW); Yueh-Hung Chung, Hsinchu City (TW); Ya-Ling Hsu, Hsinchu City (TW); Chen-Hsien Liao, Hsinchu City (TW); Sheng-Yen Cheng, Hsinchu City (TW); Ming-Lung Chen, Hsinchu City (TW); Kun-Cheng Tien, Hsinchu City (TW)

(73) Assignee: AUO Corporation, Hsinchu City (TW)

(21) Appl. No.: 19/086,149

(22) Filed: Mar. 21, 2025

(30) Foreign Application Priority Data
Mar. 22, 2024 (TW) 113110661

(51) Int. Cl. H10H 29/34

(52) U.S. Cl. CPC H10H 29/34

(57) ABSTRACT

A display device including multiple light emitting units arranged adjacent to each other is provided. The light emitting unit includes multiple pixels. Each of the pixels includes multiple sub-pixels, and the sub-pixels are arranged in an L shape. Both sides of the pixel are substantially parallel to both sides of the light emitting unit. The light emitting units include a first light emitting unit and a second light emitting unit that are adjacent to each other. The first light emitting unit has multiple first pixels and the second light emitting unit has multiple second pixels. The first pixels and the second pixels are centrally symmetrical.

### CROSS-REFERENCE TO RELATED APPLICATION

This application claims the priority benefit of Taiwan application serial no. 113110661, filed on Mar. 22, 2024. The entirety of the above-mentioned patent application is hereby incorporated by reference herein and made a part of this specification.

### BACKGROUND

### Technical Field

The disclosure relates to an electronic device, and in particular to a display device.

### Description of Related Art

In recent years, with the widespread application of display devices, user demands for the size of display devices and the display screen have gradually increased. Spliced displays are considered one of the solutions to meet these demands. For example, a plurality of smaller light emitting units may be transferred onto a target circuit board to form a large-sized spliced display device, thereby meeting user demands for large-sized displays. However, in frameless spliced displays, the splicing locations between the light emitting units are prone to issues such as uneven color distribution, color deviation, or insufficient brightness. As a result, splicing locations in the display screen of the spliced display device may form visible black lines or yellow lines, which may be noticed by the user and negatively impact the viewing experience. Therefore, improving this phenomenon has become a challenge for relevant manufacturers.

### SUMMARY

The disclosure provides a display device that effectively improve the issue of color deviation that easily occurs at the splicing locations of spliced displays, resulting in an improved display effect.

In an embodiment of the disclosure, the display device includes multiple light emitting units arranged adjacent to each other. Each of the light emitting units includes multiple pixels. Each of the pixels includes multiple sub-pixels, and the sub-pixels are arranged in an L shape. Both sides of each of the pixels are substantially parallel to both side edges of each of the light emitting units. The light emitting units include a first light emitting unit and a second light emitting unit that are adjacent to each other. The first light emitting unit has multiple first pixels, and the second light emitting unit has multiple second pixels. The first pixels and the second pixels are centrally symmetrical.

Based on the above, in the display device in the embodiment of the disclosure, the pixels of the light emitting unit are arranged in an L shape, which may also be understood as an array of sub-pixels arranged in a right-angled triangle pattern. Therefore, when the light emitting units need to be cut during the packaging process, the pixels in an L shape at the edges of the light emitting units have a lower risk of breakage compared to conventional pixels arranged in a rectangular pattern. In addition, on two adjacent light emitting units, the pixels of each of the two light emitting units are arranged in a centrally symmetrical manner. That is, the pixel arrangement pattern of one light emitting unit differs from the pixel arrangement pattern of the adjacent light emitting unit by substantially 180 degrees. As a result, the light beams of different colors emitted by the pixels on both sides of the splicing location may be fully mixed. When the display device is illuminated, the problem of splicing lines or dark lines of different colors that are prone to occur at the splicing locations may be effectively reduced, further enhancing the image quality of the display screen and improving the viewing experience of the user.

To make the features and advantages of the disclosure more comprehensible, several embodiments accompanied with drawings are described in detail as follows.

### BRIEF DESCRIPTION OF THE DRAWINGS

FIG. 1 is a top view schematic diagram of a display device in an embodiment of the disclosure.

FIG. 2 is an enlarged schematic diagram of a region A of the display device in FIG. 1.

FIGS. 3 to 25 are top view schematic diagrams of the modified embodiments of the disclosure.

### DESCRIPTION IN THE EMBODIMENTS

The terms “about,” “approximately,” “essentially,” or “substantially” as used herein include the stated value and an average value within an acceptable deviation range determined by a person having ordinary skill in the art, considering the specific quantity of the discussed measurement and the errors related to the measurement (i.e., the limitations of the measurement system). For example, “about” may refer to being within one or more standard deviations of the stated value or within +30%, +20%, +15%, +10%, or +5%, for example. Furthermore, the terms “about,” “approximately,” “essentially,” or “substantially” as used herein may be selected to have a more acceptable deviation range or standard deviation depending on the nature of the measurement, the nature of the cutting, or other properties, and a single standard deviation does not need to apply to all properties.

In the drawings, for clarity, the thicknesses of layers, films, panels, regions, and the like have been enlarged. It should be understood that when an element such as a layer, film, region, or substrate is described as being “on” another element or “connected to” another element, it may be directly on or connected to the other element, or an intermediate element may also be present. Conversely, when an element is described as being “directly on” another element or “directly connected to” another element, no intermediate element is present. As used herein, “connected” may refer to physical and/or electrical connection. Furthermore, “electrically connected” may include the presence of other elements between two elements.

Exemplary embodiments of the disclosure will now be described in detail with reference to the accompanying drawings. Wherever possible, the same reference numerals are used in the drawings and descriptions to indicate the same or similar parts.

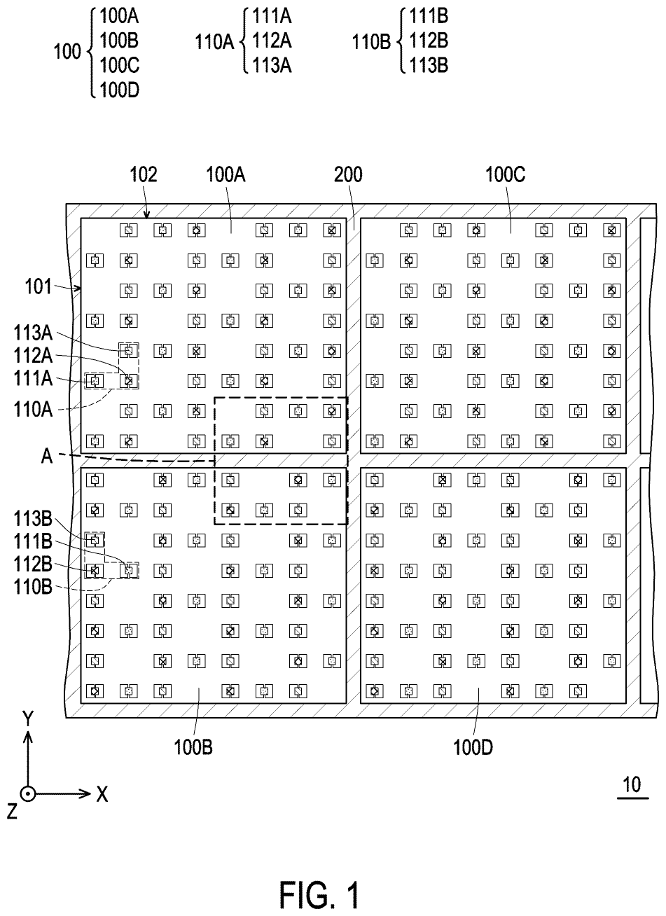

FIG. 1 is a top view schematic diagram of a display device in an embodiment of the disclosure. Referring to FIG. 1, a display device 10 may include multiple light emitting units 100 and a driving substrate 200. The light emitting units 100 are disposed on the driving substrate 200 and overlap with and are electrically connected to the driving substrate 200 in a Z direction. However, the disclosure does not limit the electrical connection manner of the light emitting units 100. Additionally, FIG. 1 schematically illustrates four light emitting units, namely a first light emitting unit 100A, a second light emitting unit 100B, a third light emitting unit 100C, and a fourth light emitting unit 100D. The light emitting units may be arranged in an array in an X direction and a Y direction, for example, in a 2×3 matrix array, a 3×3 matrix array, a 4×4 matrix array, or an array with another quantity. The disclosure is not limited thereto. The X direction, the Y direction, and the Z direction as described herein may be substantially perpendicular to each other. However, the disclosure is not limited thereto.

Furthermore, the first light emitting unit 100A, the second light emitting unit 100B, the third light emitting unit 100C, and the fourth light emitting unit 100D may each include multiple pixels to provide display light beams in a Z direction. For example, the first light emitting unit 100A has multiple first pixels 110A, and the second light emitting unit 100B has multiple second pixels 110B. The pixels may further include multiple sub-pixels. For example, the first pixel 110A may include a sub-pixel 111A that emits red light, a sub-pixel 112A that emits green light, and a sub-pixel 113A that emits blue light. Similarly, the second pixel 110B may include a sub-pixel 111B that emits red light, a sub-pixel 112B that emits green light, and a sub-pixel 113B that emits blue light. That is, the sub-pixel 111A and the sub-pixel 111B may be red sub-pixels, the sub-pixel 112A and the sub-pixel 112B may be green sub-pixels, and the sub-pixel 113A and the sub-pixel 113B may be blue sub-pixels. The third light emitting unit 100C and the fourth light emitting unit 100D may also have the same configuration, and further descriptions thereof are omitted here. Additionally, each of the sub-pixels of the above colors may be a single micro light emitting diode (micro LED), a single mini light emitting diode (mini LED), or a single organic light emitting diode (OLED). The disclosure is not limited thereto. The structure of each of the sub-pixels of the above colors may also be a face-up type LED, a vertical type LED, or a flip-chip type LED. The disclosure is not limited thereto. Among the first pixels 110A and the second pixels 110B, the quantity ratio of various light emitting diodes may be correspondingly adjusted as needed. The disclosure is not limited thereto. The sub-pixels may be electrically connected to the light emitting units 100 to provide a display image in the Z direction. In other embodiments, the light emitting units 100 may also be non-self-emitting light emitting units. For example, each of the light emitting units 100 may include a liquid crystal layer, a backlight module, and a color filter, such that the display device 10 may be a spliced liquid crystal display. The disclosure is not limited thereto.

On the other hand, each of the light emitting units 100 may include alternately stacked redistribution layers, including multiple metal layers (not shown) and multiple insulating layers (not shown). One of these metal layers is used to form multiple conductive patterns, another is used to form multiple pad patterns, and yet another is used to form multiple transition patterns. These transition patterns may be electrically connected to the conductive patterns and the pad patterns through multiple contact holes in the insulating layers. That is, the metal layers may form multiple electrically insulated conductive paths in the light emitting unit 100. The sub-pixels of different colors, which are bonded to the conductive patterns located above the light emitting unit 100, may be electrically connected to the pad patterns through the conductive paths. The light emitting unit 100 may be electrically bonded to the driving substrate 200 through the pad patterns. In other words, at least one driving circuit chip is included in the driving substrate 200, wherein the driving circuit chip includes, for example, transistors or integrated circuits (ICs) that may be electrically connected to the sub-pixels to control the display signals of the sub-pixels. However, the disclosure is not limited thereto.

It is noteworthy that in this embodiment, the sub-pixels of each of the light emitting units 100 may be arranged in an “L” shape resembling an English letter or in a right-angled triangle arrangement. For example, in the first light emitting unit 100A, in the first pixel 110A, the sub-pixel 111A and the sub-pixel 112A may be arranged in the X direction, and the sub-pixel 112A and the sub-pixel 113A may be arranged in the Y direction. Similarly, in the second light emitting unit 100B, in the second pixel 110B, the sub-pixel 111B and the sub-pixel 112B may be arranged in the X direction, and the sub-pixel 112B and the sub-pixel 113B may be arranged in the Y direction. As a result, both the first pixel 110A and the second pixel 110B form L-shaped pixels. Taking the first pixel 110A as an example, one side of the L-shaped pixel is substantially parallel to a side 101 of the first light emitting unit 100A, and the other side of the L-shaped pixel is substantially parallel to another side 102 of the first light emitting unit 100A.

It is noteworthy that, in addition to the L-shaped arrangement of the pixels in each of the light emitting units 100, the pixels in adjacent light emitting units 100 may be arranged in a centrally symmetrical manner. It should be noted that in this specification, when no other light emitting unit is present between the first light emitting unit 100A and the second light emitting unit 100B, the first light emitting unit 100A and the second light emitting unit 100B are considered adjacent to each other. Therefore, the first light emitting unit 100A and the third light emitting unit 100C may also be considered adjacent to each other.

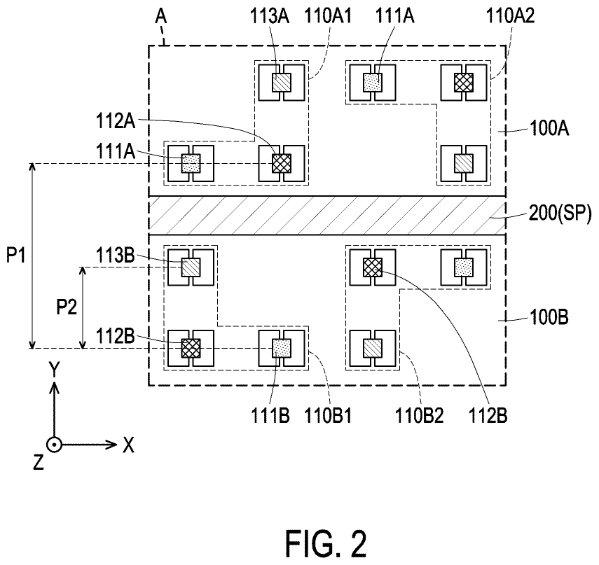

FIG. 2 is an enlarged schematic diagram of a region A of the display device in FIG. 1. The region A enlarges a portion of the area where the first light emitting unit 100A and the second light emitting unit 100B are adjacent, and the portion of the driving substrate 200 exposed between the first light emitting unit 100A and the second light emitting unit 100B may be regarded as a splicing region SP of the display device 10. Referring to FIGS. 1 and 2, for ease of explanation, the first light emitting unit 100A schematically shows two first pixels 110A, namely a first pixel 110A1 and a first pixel 110A2, while the second light emitting unit 100B schematically shows two second pixels 110B, namely a second pixel 110B1 and a second pixel 110B2. In this embodiment, the arrangement of the pixels on each of the light emitting units 100 may be completely identical during the manufacturing process. However, during the splicing process, the arrangement direction of the adjacent first light emitting unit 100A and the third light emitting unit 100C may both be in the X direction, while the arrangement direction of the second light emitting unit 100B and the fourth light emitting unit 100D may both be in the negative X direction. As a result, after the splicing is completed, the arrangement pattern of the first pixels 110A and the arrangement pattern of the second pixels 110B may be in a centrally symmetrical arrangement.

Referring to FIG. 2, for example, when taking the shape centers of the first pixel 110A1 and the first pixel 110A2 as the rotation point and the Z direction as the rotation axis, after rotating 180 degrees, the shape and each sub-pixel of the first pixel 110A1 and the second pixel 110B2, as well as the first pixel 110A2 and the second pixel 110B1, may be substantially identical. From another perspective, the first pixel 110A1 and the second pixel 110B2 may together form a centrally symmetrical pattern, and the first pixel 110A2 and the second pixel 110B1 may together form a centrally symmetrical pattern.

Through the above configuration, on opposite sides of the splicing region SP in the Y direction, the light beams of different colors emitted between the adjacent first pixel 110A1 and the second pixel 110B1 may complement each other. For example, the sub-pixel 111A and the sub-pixel 112A of the first pixel 110A1 respectively emit a red light beam and a green light beam, which may fully mix with the blue light beam emitted by the sub-pixel 113B in the second pixel 110B1 on the other side of the splicing region SP. As a result, the display image near the splicing region SP may allow a viewer to observe a white display light beam, thereby reducing or eliminating the color deviation phenomenon in the splicing region SP. On the other hand, compared to conventionally arranged rectangular pixels, the L-shaped first pixels 110A1, 110A2 and the second pixels 110B1, 110B2, which are respectively located at the edges of the first light emitting unit 100A and the second light emitting unit 100B, may have a lower risk of breakage when cutting is required during the manufacturing process of the light emitting units, thereby improving the yield rate in the product manufacturing process. It is specifically noted that the phrase “the first pixel 110A1 and the second pixel 110B1 are adjacent” means that no other pixel is present within the pitch between the first pixel 110A1 and the second pixel 110B1. Similarly, the description “two sub-pixels are adjacent” means that no other sub-pixel is present within the pitch between the two sub-pixels.

It should be noted that the disclosure uses the region A and the splicing region SP on both sides in the Y direction as an exemplary description. In other areas of the display device 10, such as the splicing region between the first light emitting unit 100A and the third light emitting unit 100C in FIG. 1, similar effects may also be achieved. The relevant content may be referred to in the above paragraphs, and further descriptions thereof are omitted here.

Referring again to FIG. 2, on the other hand, to ensure that the light intensity at the splicing region SP is consistent with the light intensity at the center of the light emitting unit 100, the pitch between the pixels of different light emitting units 100 may be substantially the same as the pitch between the pixels within the same light emitting unit 100. For example, a first pitch P1 between the first pixel 110A1 and the second pixel 110B1 may be defined as the distance from the center of the sub-pixel 112A of the first pixel 110A1 to the center of the sub-pixel 111B of the second pixel 110B1. The first pitch P1 may be substantially the same as the pitch between the first pixel 110A1 and the first pixel 110A2, or the same as the pitch between the second pixel 110B1 and the second pixel 110B2. For example, the pitch between the sub-pixel 113B of the second pixel 110B1 and the sub-pixel 112B of the second pixel 110B2 may be substantially equal to the size of the first pitch P1. Furthermore, since the pixels in the embodiment of the disclosure are L-shaped pixels, in FIG. 2, no other sub-pixel may be present on the first pitch P1. Similarly, there may be no other sub-pixel present on the pitch between the sub-pixel 111A of the first pixel 110A2 and the sub-pixel 112B of the second pixel 110B2.

On the other hand, the pitch between the sub-pixels within a single pixel may be smaller. For example, the pitch between the sub-pixels of the second pixel 110B1 may be defined as a second pitch P2, which may be defined as the pitch between the sub-pixel 112B and the sub-pixel 113B. The second pitch P2 may also be the same as the pitch between the sub-pixel 111B and the sub-pixel 112B. Furthermore, the ratio of the first pitch P1 to the second pitch P2 may be greater than or equal to 3. In some embodiments, the first pitch P1 may be approximately 744 micrometers, and the second pitch P2 may be approximately 248 micrometers. However, the disclosure is not limited thereto. Under the above configuration, since the first pitch P1 between the pixels on the two adjacent light emitting units 100 and the pitch between the pixels within the same light emitting unit 100 may be substantially the same, when the display device 10 is in an illuminated state, the display brightness at the splicing region SP may be approximately the same as the display brightness in other areas of the light emitting unit 100. As a result, the issue of lower brightness at the seams of the spliced display, which easily forms dark lines, may be reduced or avoided, effectively improving the display image quality of the display device 10.

It is noteworthy that the adjacent pixels within the same light emitting unit 100 may be alternately arranged. For example, the first pixel 110A1 and the first pixel 110A2 on the first light emitting unit 100A are adjacent to each other and alternately arranged. If the first pixel 110A1 forms a line-symmetrical pattern with respect to a straight line extending in the X direction as a symmetry axis, the shape of the line-symmetrical pattern may be substantially identical to the shape of the first pixel 110A2. Similarly, the second pixel 110B1 and the second pixel 110B2 on the second light emitting unit 100B are adjacent to each other and alternately arranged. If the second pixel 110B1 forms a line-symmetrical pattern with respect to a straight line extending in the X direction as a symmetry axis, the shape of the line-symmetrical pattern may be substantially identical to the shape of the second pixel 110B2. However, the disclosure is not limited thereto.

The following are additional modified embodiments that further illustrate the disclosure. The same components are labeled with the same reference numerals, and descriptions of identical technical content are omitted. The omitted portions may be referred to in the foregoing embodiments, and further descriptions are not repeated here.

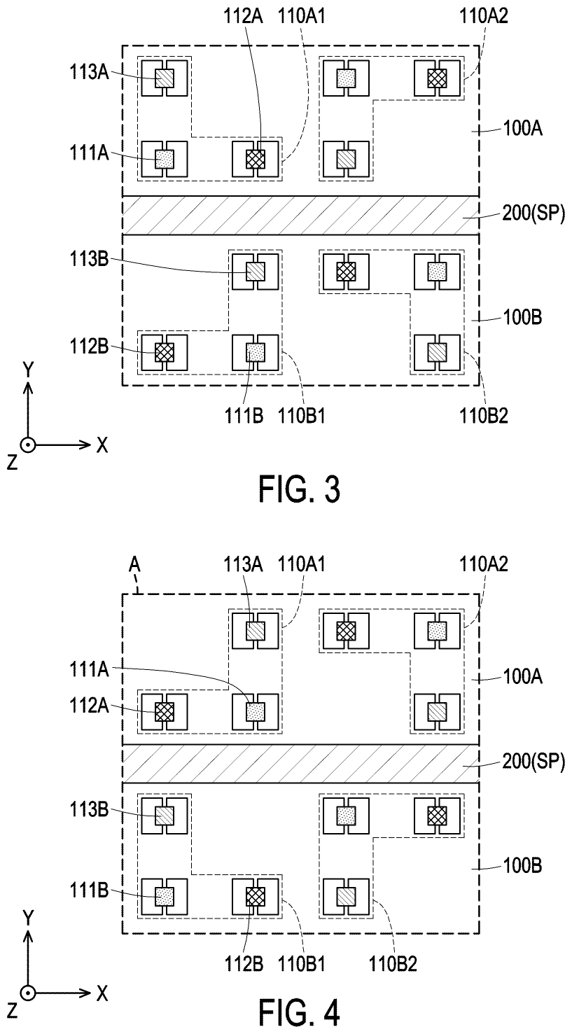

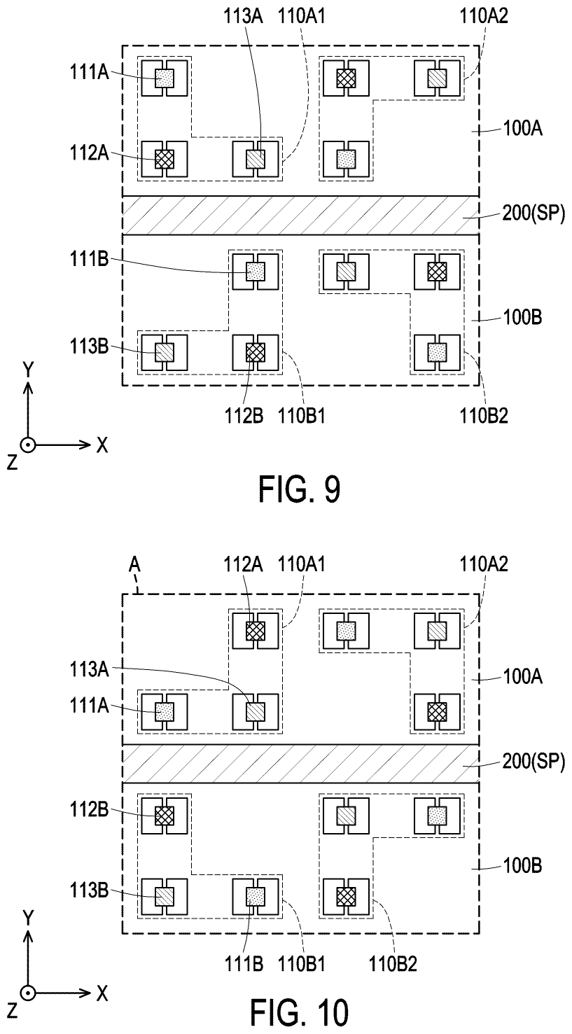

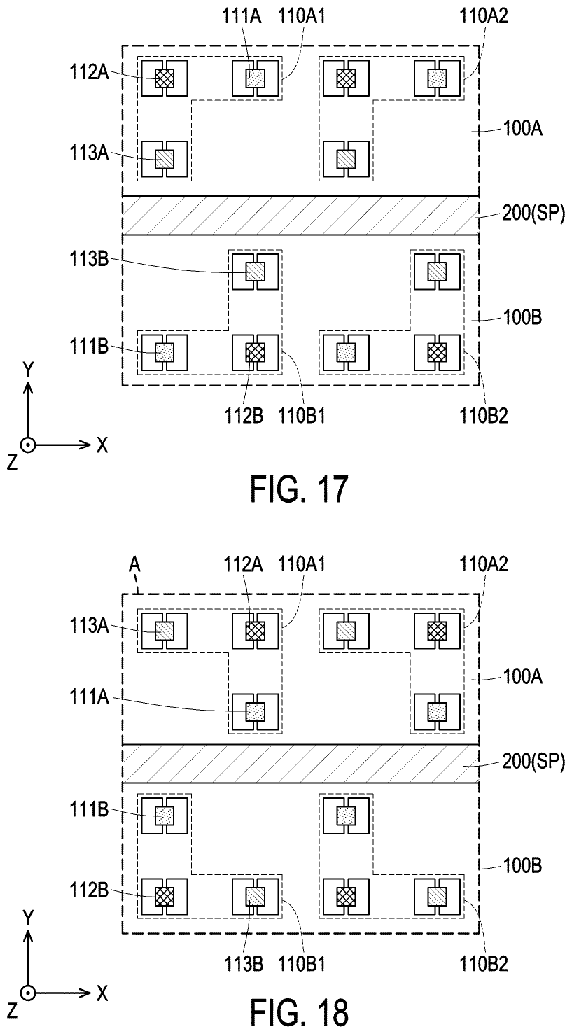

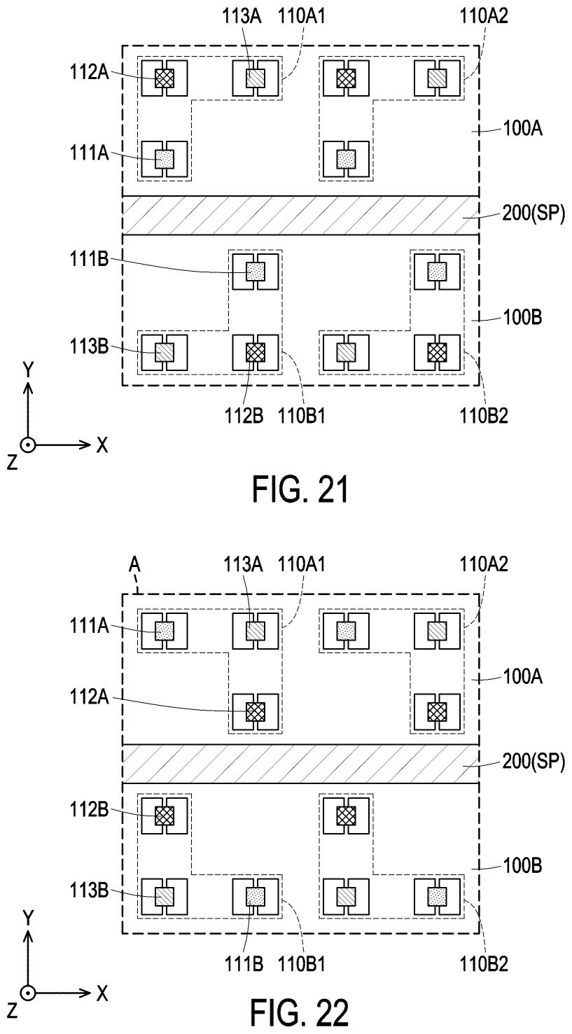

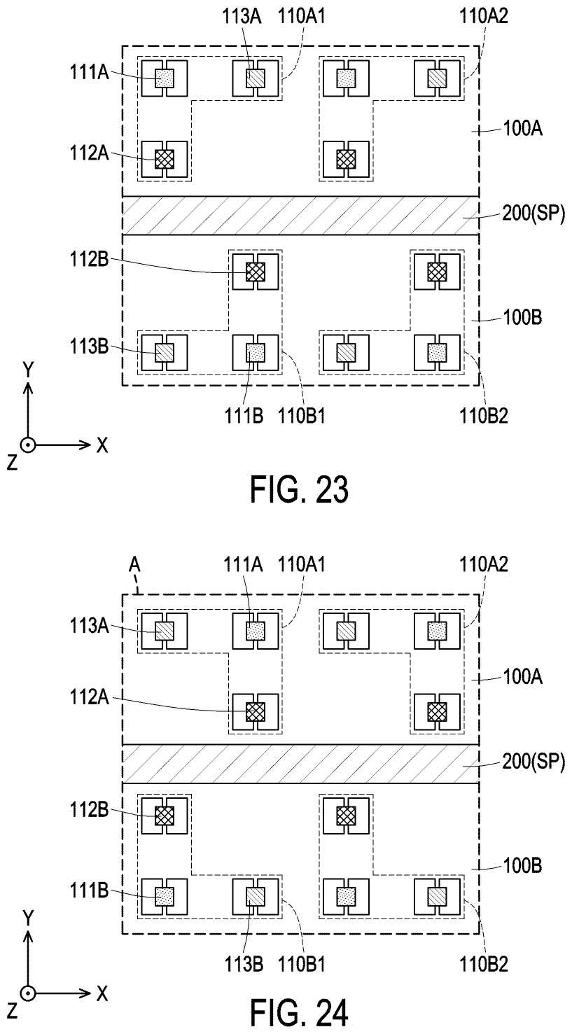

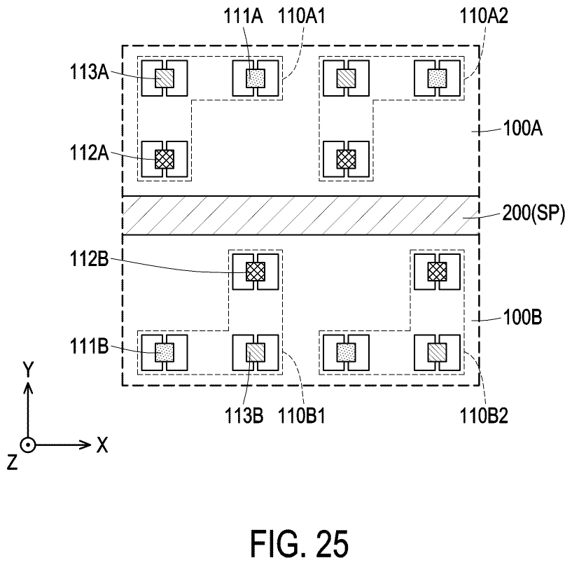

FIGS. 3 to 25 are top view schematic diagrams of various modified embodiments of the disclosure. Referring first to FIGS. 3 to 13, the pixel arrangement is similar to that of the display device 10 in FIG. 2, with the difference being that the arrangement of the sub-pixels within each pixel is different. For example, in FIGS. 2 to 13, in each first pixel 110A and second pixel 110B, the two sub-pixels that are closest to each other in the Y direction emit different display light beam colors.

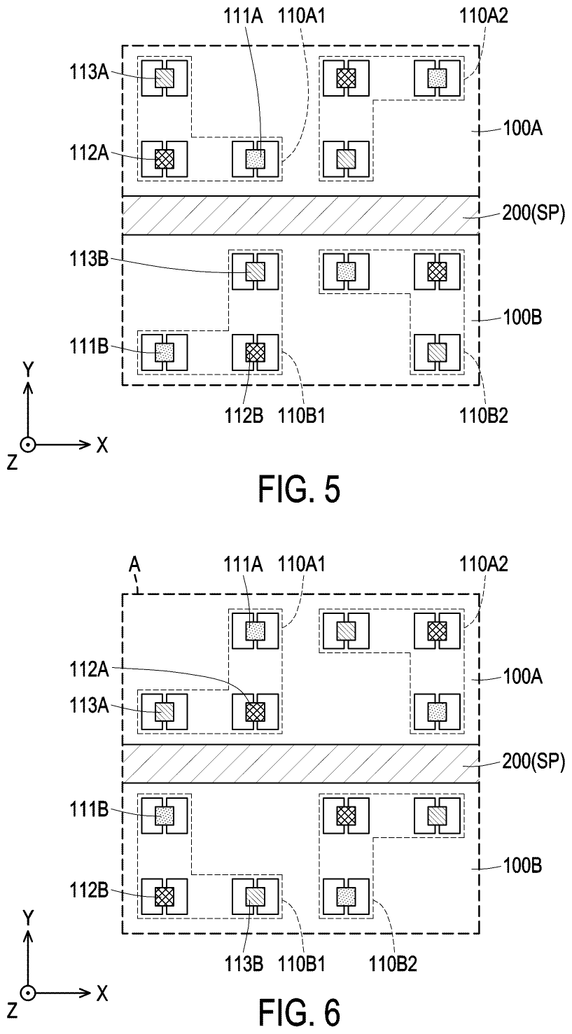

Taking FIG. 2 as an example, in the Y direction, the sub-pixel 111A of the first pixel 110A1 and the sub-pixel 113B of the second pixel 110B1 are the two closest sub-pixels. The minimum distance between the sub-pixel 111A and the sub-pixel 113B in the Y direction may be the difference between the first pitch P1 and the second pitch P2, for example, twice the second pitch P2. The subsequent modified embodiments may be deduced in the same manner, and further descriptions are not repeated here. Additionally, one of the sub-pixels 111A and 113B is a red sub-pixel that emits red light, while the other is a blue sub-pixel that emits blue light. FIGS. 5, 6, and 9 also have a similar configuration, while the arrangement sequence of the remaining sub-pixels may be interchanged arbitrarily. For example, in the modified embodiments of FIGS. 2 and 6, the difference lies in the swapped positions of the red sub-pixel 111A and the blue sub-pixel 113A in the first pixels 110A1 and 110A2, as well as the swapped positions of the red sub-pixel 111B and the blue sub-pixel 113B in the second pixels 110B1 and 110B2. Differences in other embodiments may be referred to in the preceding paragraphs and corresponding figures, and further descriptions are not repeated here.

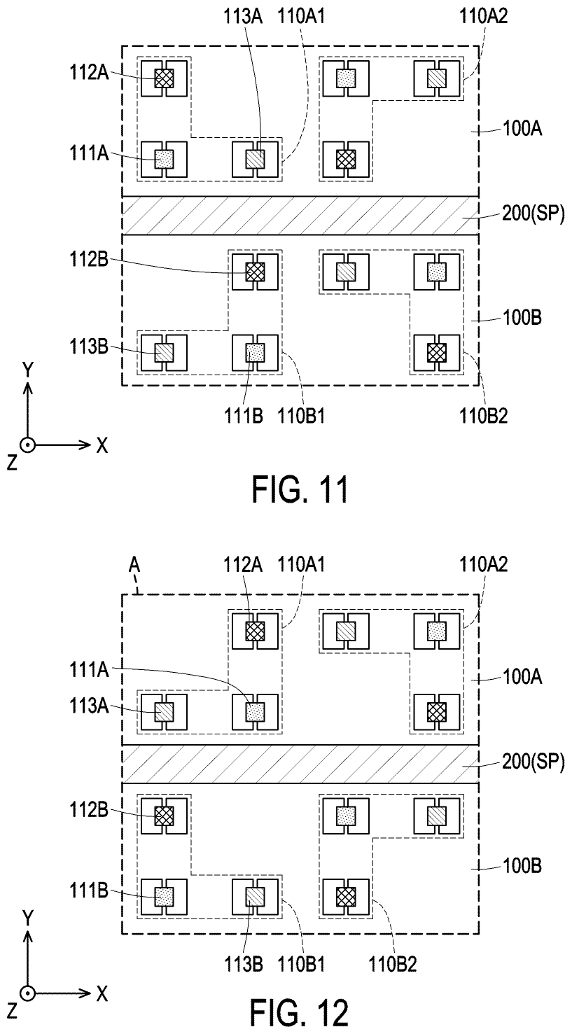

Similarly, taking FIG. 3 as an example, in the Y direction, the sub-pixel 112A of the first pixel 110A1 and the sub-pixel 113B of the second pixel 110B1 are the two closest sub-pixels. One of the sub-pixels 112A and 113B is a green sub-pixel that emits green light, while the other is a blue sub-pixel that emits blue light. FIGS. 4, 11, and 12 also have a similar configuration, while the arrangement sequence of the remaining sub-pixels may be interchanged arbitrarily. For example, in the modified embodiments of FIGS. 3 and 11, the difference lies in the swapped positions of the green sub-pixel 112A and the blue sub-pixel 113A in the first pixels 110A1 and 110A2, as well as the swapped positions of the green sub-pixel 112B and the blue sub-pixel 113B in the second pixels 110B1 and 110B2. Differences in other embodiments may be referred to in the preceding paragraphs and corresponding figures, and further descriptions are not repeated here.

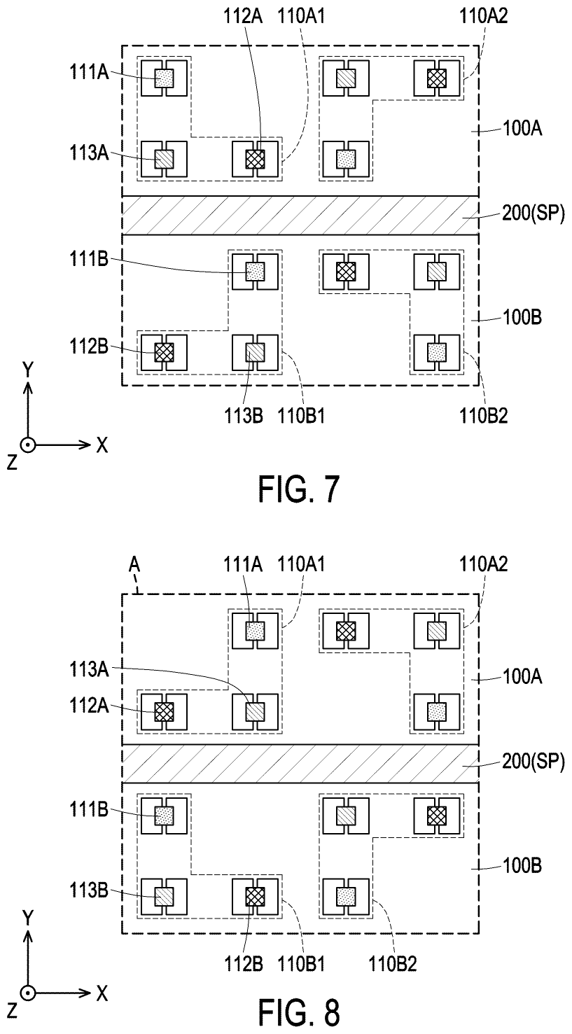

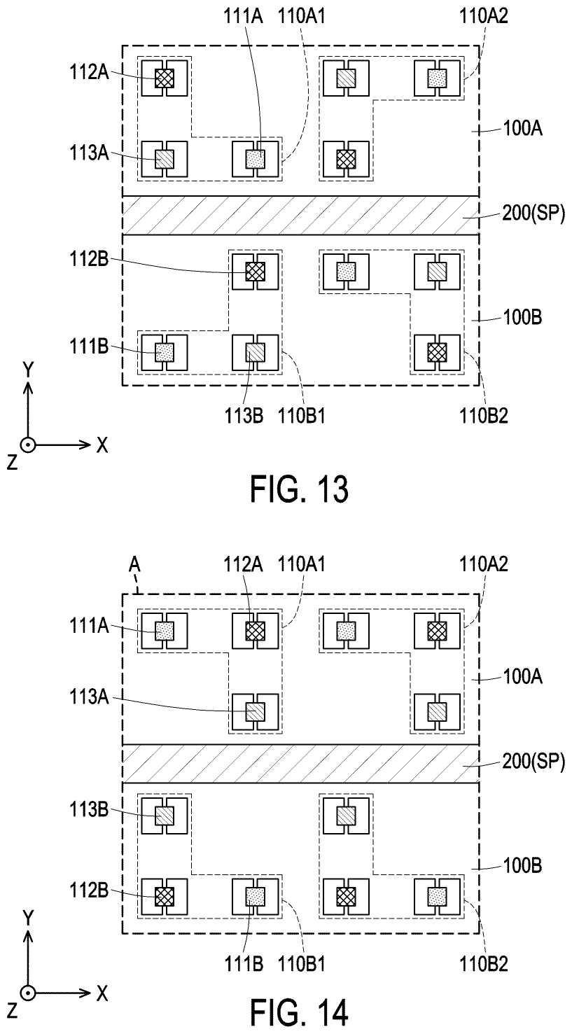

Similarly, taking FIG. 7 as an example, in the Y direction, the sub-pixel 112A of the first pixel 110A1 and the sub-pixel 111B of the second pixel 110B1 are the two closest sub-pixels. One of the sub-pixels 112A and 111B is a green sub-pixel that emits green light, while the other is a red sub-pixel that emits red light. FIGS. 8, 10, and 13 also have a similar configuration, while the arrangement sequence of the remaining sub-pixels may be interchanged arbitrarily. For example, in the modified embodiments of FIGS. 7 and 13, the difference lies in the swapped positions of the green sub-pixel 112A and the red sub-pixel 111A in the first pixels 110A1 and 110A2, as well as the swapped positions of the green sub-pixel 112B and the red sub-pixel 111B in the second pixels 110B1 and 110B2. Differences in other embodiments may be referred to in the preceding paragraphs and corresponding figures, and further descriptions are not repeated here.

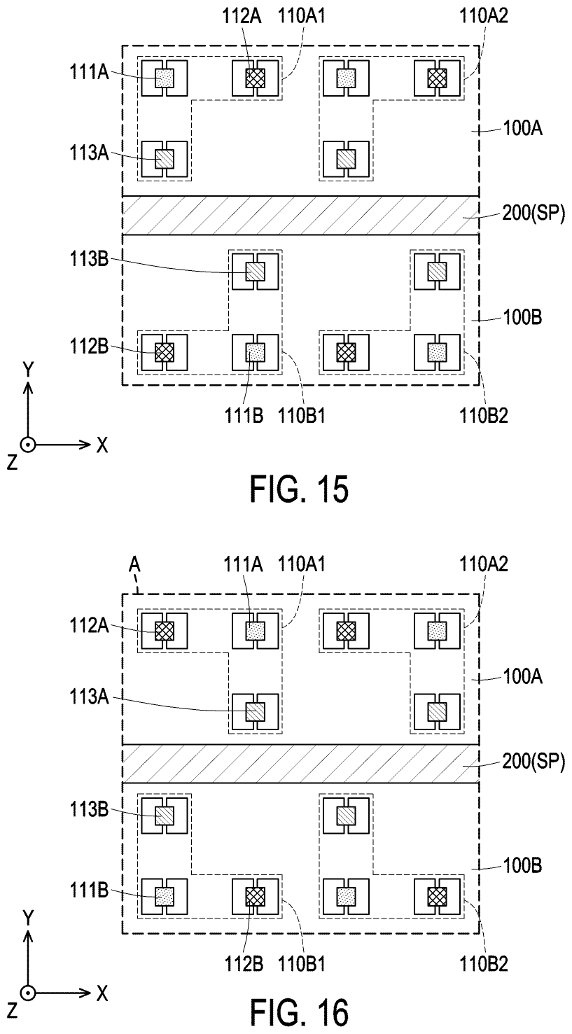

On the other hand, the arrangement shape of the pixels within the same light emitting unit 100 may also be substantially the same. For example, in the modified embodiment of FIG. 14, the first pixel 110A1 and the first pixel 110A2 on the first light emitting unit 100A may both have an arrangement profile that corresponds to the English letter “L” rotated 180 degrees in the X direction. The second pixel 110B1 and the second pixel 110B2 on the second light emitting unit 100B may both have an arrangement profile that corresponds to the English letter “L” in the X direction. The modified embodiments of FIGS. 15 to 25 may also have a similar configuration.

Furthermore, in the embodiments of FIGS. 14 to 25, in a light emitting unit 100 and another adjacent light emitting unit 100, the two sub-pixels that are closest to each other may emit the same color display light beam. For example, taking FIG. 14 as an example, the sub-pixel 113A of the first pixel 110A1 and the sub-pixel 113B of the second pixel 110B1 are the two closest sub-pixels in the Y direction, and both may emit blue light. Similarly, the embodiments of FIGS. 15 to 17 may have the same configuration as described above, and the arrangement sequence of the remaining colored sub-pixels may be interchanged with each other. For example, in the modified embodiments of FIGS. 14 and 16, the difference lies in the swapped positions of the red sub-pixel 111A and the green sub-pixel 112A in the first pixels 110A1 and 110A2, as well as the swapped positions of the green sub-pixel 112B and the red sub-pixel 111B in the second pixels 110B1 and 110B2. Differences in other embodiments may be referred to in the preceding paragraphs and corresponding figures, and further descriptions are not repeated here.

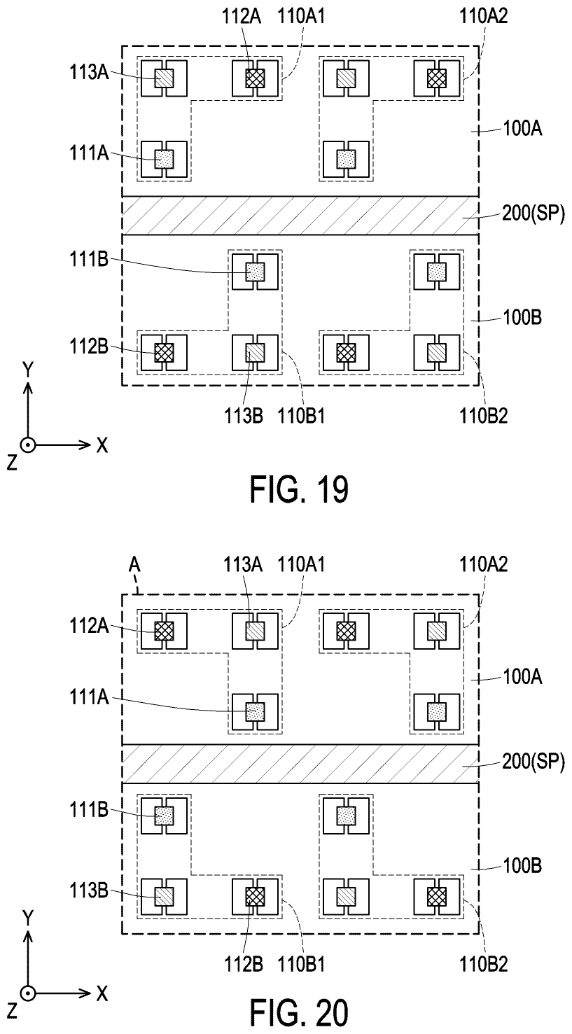

Similarly, taking FIG. 18 as an example, the sub-pixel 111A of the first pixel 110A1 and the sub-pixel 111B of the second pixel 110B1 are the two closest sub-pixels in the Y direction, and both may emit red light. Similarly, the embodiments of FIGS. 19 to 21 may have the same configuration as described above, and the arrangement sequence of the remaining colored sub-pixels may be interchanged with each other. For example, in the modified embodiments of FIGS. 18 and 20, the difference lies in the swapped positions of the green sub-pixel 112A and the blue sub-pixel 113A in the first pixels 110A1 and 110A2, as well as the swapped positions of the blue sub-pixel 113B and the green sub-pixel 112B in the second pixels 110B1 and 110B2. Differences in other embodiments may be referred to in the preceding paragraphs and corresponding figures, and further descriptions are not repeated here.

Similarly, taking FIG. 22 as an example, the sub-pixel 112A of the first pixel 110A1 and the sub-pixel 112B of the second pixel 110B1 are the two closest sub-pixels in the Y direction, and both may emit green light. Similarly, the embodiments of FIGS. 22 to 25 may have the same configuration as described above, and the arrangement sequence of the remaining colored sub-pixels may be interchanged with each other. For example, in the modified embodiments of FIGS. 22 and 24, the difference lies in the swapped positions of the red sub-pixel 111A and the blue sub-pixel 113A in the first pixels 110A1 and 110A2, as well as the swapped positions of the blue sub-pixel 113B and the red sub-pixel 111B in the second pixels 110B1 and 110B2. Differences in other embodiments may be referred to in the preceding paragraphs and corresponding figures, and further descriptions are not repeated here.

In summary, in the display device in the embodiment of the disclosure, the pixels in the light emitting unit are arranged in an L shape, resembling an English letter, or may also be understood as an array of sub-pixels arranged in a right-angled triangle pattern. Therefore, when the light emitting unit needs to be cut during the packaging process, the L-shaped pixels at the edges of the light emitting unit have a lower risk of breakage compared to conventionally arranged rectangular pixels. Furthermore, on two adjacent light emitting units, the pixels of each of the two light emitting units are arranged in a centrally symmetrical manner. That is, the arrangement pattern of the pixels in one light emitting unit and the arrangement pattern of the pixels in the adjacent light emitting unit substantially differ by 180 degrees. As a result, the light beams of different colors emitted by the pixels on both sides of the splicing location may fully mix. When the display device is illuminated, the issue of splicing lines or dark lines of different colors that are prone to appear at the splicing location may be effectively reduced, further enhancing the image quality of the display screen and improving the viewing experience of the user.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A display device, comprising:
a plurality of light emitting units, arranged adjacent to each other, wherein each of the plurality of light emitting units comprises:
a plurality of pixels, each comprising a plurality of sub-pixels, the plurality of sub-pixels being arranged in an L shape, wherein both sides of each of the plurality of pixels are substantially parallel to both side edges of each of the plurality of light emitting units,
wherein the plurality of light emitting units comprise a first light emitting unit and a second light emitting unit that are adjacent to each other, the first light emitting unit having a plurality of first pixels, the second light emitting unit having a plurality of second pixels, wherein the plurality of first pixels and the plurality of second pixels are centrally symmetrical.

2. The display device according to claim 1, wherein the plurality of sub-pixels comprise a red sub-pixel, a green sub-pixel, and a blue sub-pixel.

3. The display device according to claim 1, wherein the plurality of first pixels are close to the plurality of second pixels, a first pitch is provided between one of the plurality of first pixels and one of the plurality of second pixels, a second pitch is provided between the plurality of sub-pixels of the pixel, and a ratio of the first pitch to the second pitch is greater than or equal to 3.

4. The display device according to claim 3, wherein the plurality of sub-pixels are not provided on the first pitch.

5. The display device according to claim 2, wherein the plurality of first pixels of the first light emitting unit arranged in a first direction are alternately arranged, and two adjacent ones of the plurality of alternately arranged first pixels form a line-symmetrical pattern, a symmetry axis of the line-symmetrical pattern extending in the first direction.

6. The display device according to claim 5, wherein one of a plurality of sub-pixels of the plurality of first pixels and one of a plurality of sub-pixels of the plurality of second pixels that are closest to each other in a second direction have a different color.

7. The display device according to claim 2, wherein the plurality of first pixels of the first light emitting unit have a same arrangement shape.

8. The display device according to claim 7, wherein one of a plurality of sub-pixels of the plurality of first pixels and one of a plurality of sub-pixels of the plurality of second pixels that are closest to each other in a second direction have a same color.

9. The display device according to claim 6, wherein among the one of the plurality of sub-pixels of the plurality of first pixels and the one of the plurality of sub-pixels of the plurality of second pixels that are closest to each other in the second direction, the one is the red sub-pixel and the other one is the blue sub-pixel.

10. The display device according to claim 6, wherein among the one of the plurality of sub-pixels of the plurality of first pixels and the one of the plurality of sub-pixels of the plurality of second pixels that are closest to each other in the second direction, the one is the red sub-pixel and the other one is the green sub-pixel.

11. The display device according to claim 6, wherein among the one of the plurality of sub-pixels of the plurality of first pixels and the one of the plurality of sub-pixels of the plurality of second pixels that are closest to each other in the second direction, the one is the green sub-pixel and the other one is the blue sub-pixel.
